(19) United States
(12) Patent Application Publication
(10) Pub. No.: US 2026/0301806 A1
(43) Pub. Date: Oct. 1, 2026

(54) Adaptive Negative Bit Line Control for Memory Write Assist

(71) Applicant: QUALCOMM Incorporated, San Diego, CA (US)

(72) Inventors: Anil Chowdary KOTA, San Diego, CA (US); Hochul LEE, Los Angeles, CA (US); Ming Chien TSAI, Tainan City (TW)

(21) Appl. No.: 19/090,294

(22) Filed: Mar. 25, 2025

(51) Int. Cl. G11C 11/419

(52) U.S. Cl. CPC G11C 11/419

(57) ABSTRACT

A memory is with an adaptive negative boost circuit that adapts the boost capacitance used to apply a negative bit line boost voltage during a write operation to a bank of bitcells based upon an address of the bank of bitcells.

### TECHNICAL FIELD

This application relates to memories, and more particularly to memories with adaptive negative bit line boost control for memory write assist.

### BACKGROUND

A static random-access memory (SRAM) bitcell stores a data bit through a pair of cross-coupled inverters. Depending upon the binary state of the stored data bit, a p-type metal-oxide semiconductor (PMOS) transistor in one of the cross-coupled inverters charges a data node to a memory power supply voltage. During a write operation in which the binary content of the bitcell is changed, an n-type metal-oxide semiconductor (NMOS) access transistor functions to discharge the same data node while the PMOS transistor continues to charge the data node. The resulting NMOS/PMOS struggle slows the write operation speed and consumes power.

### SUMMARY

In accordance with an aspect of the disclosure, a memory is provided that includes: a write driver having a negative boost ground node; an adaptive negative boost circuit including: a first boost capacitor having a first terminal coupled to the negative boost ground node; a second boost capacitor having a first terminal coupled to the negative boost ground node; a series of inverters coupled between a first node for a boost enable signal and a second terminal of the first boost capacitor, wherein the series of inverters includes a final inverter having an output terminal coupled directly to the second terminal of the first boost capacitor; and a logic gate having a first input terminal coupled to a second node for a bank selection signal, a second input terminal coupled to an input terminal of the final inverter, and an output terminal coupled to a second terminal of the second boost capacitor.

In accordance with another aspect of the disclosure, a write assist method for a memory is provided that includes: applying a first negative bit line boost using a first boost capacitor during a boost period of a first write operation to a first bank of bitcells; and applying a second negative bit line boost using both the first boost capacitor and a second boost capacitor during a boost period of a second write operation to a second bank of bitcells, wherein the first bank of bitcells is positioned between the second bank of bitcells and a write driver for the first write operation and for the second write operation.

Finally, in accordance with yet another aspect of the disclosure, a memory is provided that includes: a write driver having a negative boost ground node; and an adaptive negative boost circuit configured to use a first boost capacitance to apply a first negative boost voltage to the negative boost ground node during a boost period of a write operation to a first bank of bitcells by the write driver and configured to use the first boost capacitance and a second boost capacitance to apply a second negative boost voltage to the negative boost ground node during a boost period of a write operation to second bank of bitcells by the write driver.

These advantage features may be better appreciated by a consideration of the following detailed description.

### BRIEF DESCRIPTION OF THE DRAWINGS

FIG. 1A illustrates a memory includes an adjacent bank and a remote bank.

FIG. 1B is a cross-sectional view of the memory of FIG. 1A.

FIG. 2 is a diagram of a memory including an adaptive negative boost circuit in accordance with an aspect of the disclosure.

FIG. 3 is a circuit diagram of an adaptive negative boost circuit in accordance with an aspect of the disclosure.

FIG. 4 is a flowchart for a method of adaptive negative bit line boosting in accordance with an aspect of the disclosure.

FIG. 5 illustrates some example electronic systems incorporating a memory with adaptive negative bit line boosting in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

A write operation may involve changing the binary content of a bitcell such that a data node that is being charged by a PMOS transistor in one of the bitcell's cross-coupled inverters must be discharged during the write operation through an NMOS access transistor to a grounded bit line. The faster the NMOS access transistor may discharge the data node, the faster is the memory operating speed. Various forms of write assist may be used to decrease the time necessary for the NMOS access transistor to discharge the data node despite the charging by the PMOS transistor and thus increase the memory speed. One form of write assist for a static random-access memory (SRAM) is known as a negative bit line boost. In a negative bit line boost operation, the grounded bit line is temporarily boosted to a negative voltage during a negative bit line boost period. This negative voltage on the bit line effectively increases the strength of the NMOS access transistor with respect to its struggle with the PMOS transistor that would otherwise continue to charge the data node to a memory power supply voltage. The increased strength of the NMOS access transistor allows it to more quickly discharge the data node so that the write operation speed is increased accordingly. Without the negative bit line boost, the NMOS access transistors may need to be sized larger, which increases the memory footprint on the semiconductor die and thus raises manufacturing costs. But with the negative bit line boost, the NMOS access transistors may be relatively smaller, which decreases the amount of semiconductor die space occupied by the memory and thus lowers manufacturing costs.

During a write operation, a write driver couples through a write column multiplexer to a selected column from a plurality of multiplexed columns. Prior to the write operation, a pair of bit lines in each column from the plurality of multiplexed columns is precharged. Depending upon the binary value of the bit being written to a bitcell in the selected column, the write driver maintains the charging of one of the bit lines in the bit line pair for the selected column while discharging a remaining bit line in the bit line pair to ground. To provide the negative boost to the discharged one of the bit lines, a memory may include a negative bit line boost circuit with a boost capacitor. During a boost period of a write operation, the negative bit line boost circuit applies a negative voltage to the discharged bit line. To apply this negative voltage, the boost capacitor has its cathode coupled to a negative boost ground node that couples through the write driver and the write column multiplexer to the discharged bit line. An anode of the boost capacitor couples to a node for a boost signal. With the boost signal in a default charged state, the anode of the boost capacitor is charged to the memory power supply voltage whereas its cathode is grounded, which charges the boost capacitor. During the boost period, the boost signal is discharged to ground, which grounds the anode of the boost capacitor. Since the anode was positively charged with respect to the cathode of the boost capacitor, the grounding of the anode causes the cathode to be pulled to a negative voltage. In this fashion, the boost capacitor functions to pull the negative boost ground node (and thus the corresponding discharged bit line) to a negative voltage during the boost period.

One factor that affects the operation of a negative bit line boost circuit is the arrangement of the bitcells into banks. In that regard, the bitcells could be arranged into one single array having rows and columns of bitcells. A corresponding word line traverses each row whereas a corresponding pair of bit line traverses each column. As the number of columns of bitcells increases, so would the length of the word lines. The resulting length of the word lines increases their capacitance and thus slows the memory operation. Similarly, as the number of rows increases, the length of the bit lines increases. This increased bit line length increases the bit line capacitance and thus slows memory operation. To increase the speed of memory read and write operations, it is thus traditional to arrange the bitcells into banks, with each bank having its own rows and columns. In this fashion, the word line and bit line capacitances are kept at manageable levels. Although the word lines and columns for the banks are separate, input and output latches are common to several banks to reduce the die space demands. The resulting input and output latches may thus be denoted as global input/output (GIO) latches since they are shared by more than one bank. For example, a GIO latch may be placed between a first pair of banks and a second pair of bank such that it is shared by all four banks. More generally, a collection of the various GIO latches may be simply denoted as a GIO.

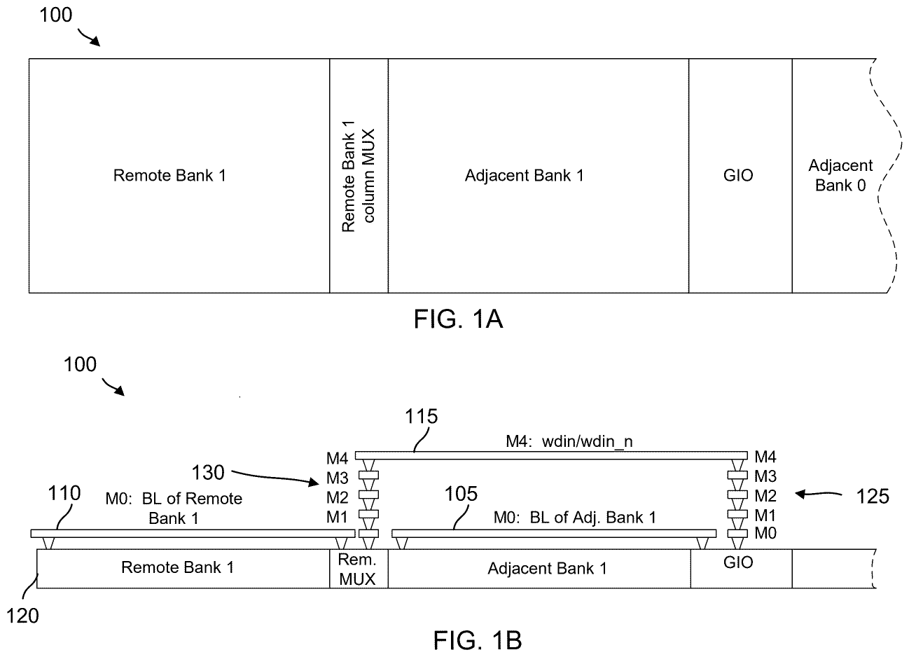

An example memory 100 with a GIO between an adjacent bank 1 and an adjacent bank 0 is shown in FIG. 1A. As implied by their names, the adjacent bank 1 and the adjacent bank 0 each have an edge that abuts (is adjacent to) a corresponding edge of the GIO. The GIO includes a write driver (not illustrated) that generates a write driver signal (wdin) and its complement (wdin_n) for writing to a selected bank. A remote bank 1 is separated from the GIO by a remote bank 1 write column multiplexer (MUX). A similar write column multiplexer for the adjacent bank 1 is not illustrated but may be included within the GIO. A cross-section of the memory 100 is shown in FIG. 1B. A semiconductor substrate 120 includes the active devices such as transistors for the memory 100. Various metal layers that are stacked above an active surface of the semiconductor substrate 100 are patterned to form the word lines and bit lines (and also to form leads for other signals, ground, and power) for the memory 100. For example, a lower-most metal layer M0 may be patterned to form a bit line 105 of the adjacent bank 1. Given that the write driver and write column multiplexer for the adjacent bank 1 are located in the GIO, the bit line 105 may merely extend slightly longer than the column length (which may be denoted as the height) for the adjacent bank 1 to couple to the write column multiplexer in the GIO. A negative boost circuit (not shown in FIGS. 1A and 1B) in the GIO that applies a negative bit line voltage through the write driver and the write column multiplexer to the bit line 105 is thus not subjected to a significant resistive loss due to its relative closeness to the adjacent bank 1.

In contrast to the adjacent bank 1, the remote bank 1 is separated from the GIO by its write column multiplexer and by the height of the adjacent bank 1. The write driver in the GIO cannot couple to a bit line 110 for the remote bank 1 through a write driver line extending from the GIO in the M0 metal layer since that metal layer is occupied by the bit lines. A write driver lead 115 for the wdin (or the wdin_n) write driver signal may thus be routed in an M4 metal layer across the height of the adjacent bank 1 from the GIO. To couple to the write driver lead 115, the write driver drives a via stack 125 that couples through the intervening metal layers M0, M1, M2, and M3 to reach the write driver lead 115 in the M4 metal layer. The write driver lead 115 then couples through another via stack 130 to the write column multiplexer for the remote bank 1. But note that the negative bit line boost circuit that is integrated with the write driver in the GIO will encounter increased resistance with regard to applying a negative bit line boost to the bit line 110 as compared to bit line 105. This increased resistance comes from the length of the write driver line 115 that must extend across the height of the adjacent bank 1 before it may couple through the remote bank 1 write column multiplexer to the bit line 110. In contrast, the write driver needs no such extended leads to couple to the adjacent bank 1 write column multiplexer as they are adjacent to each other within the GIO.

It is convenient for the boost capacitor in the negative bit line boost circuit to be formed by the gate capacitance of a boost transistor. However, a metal-layer boost capacitor may be used in alternative implementations. Regardless of how the boost capacitor is formed, its capacitance must be sufficient such that the negative boost it produces is adequate for the remote bank 1 given the resistive losses through the write driver lead 115. This increase in the boost capacitance undesirably increases the memory power consumption.

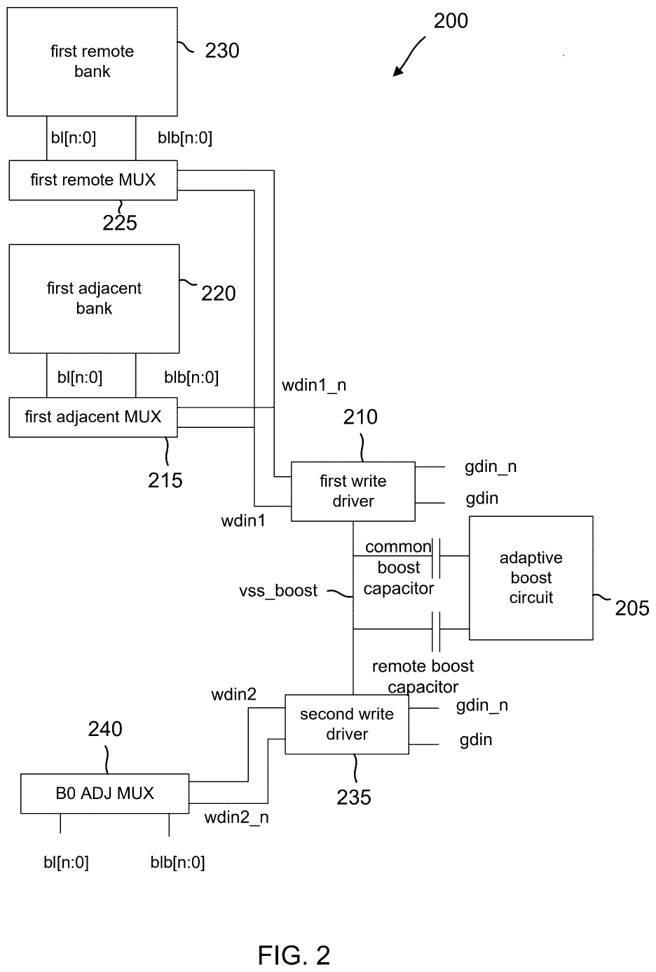

To advantageously lower the power consumption, an adaptive negative boost circuit for a write driver is disclosed that adapts the boost capacitance based upon whether the write operation is directed to an adjacent bank or a remote bank. Should the write driver be writing to an adjacent bank, the adaptive negative boost circuit uses only a first boost capacitor. But if the write driver is writing to a remote bank, the adaptive negative boost circuit uses not only the first boost capacitor but also a second boost capacitor. In this fashion, the boost capacitance is increased or decreased depending upon the distance of the bank from the write driver and negative bit line boost circuit. An example memory 200 is shown in FIG. 2. An adaptive negative boost circuit 205 (which may also be denoted herein as an adaptive boost circuit for brevity) includes at least a common boost capacitor and a remote boost capacitor that are shown separately from the adaptive boost circuit 205 for illustration clarity. The common boost capacitor is also denoted herein as a first boost capacitor. Similarly, the remote boost capacitor is also denoted herein as a second boost capacitor. One terminal of each of the boost capacitors couples to a ground boost node vss_boost. As will be explained further herein, the adaptive boost circuit 205 includes at least one transistor (not shown in FIG. 2) that grounds the vss_boost node during the non-boost portion of a write operation. During a boost period of the write operation, the adaptive boost circuit 205 switches off this transistor to float the vss_boost node so that one or more of the boost capacitors may apply a negative bit line boost voltage to the vss_boost node.

Prior to the boost period, the vss_boost node functions as a ground node for a first write driver 210 and a second write driver 235. The first write driver 210 drives the write operations to a first pair of SRAM banks 220 and 230. Similarly, the second write driver 235 drives the write operations to a second pair of banks (not illustrated but symmetrically arranged as shown for the first pair of banks 220 and 230). Each bank may also be denoted as an array in that it has its own rows and columns of bitcells (not illustrated). During a write operation to one of the banks in the first pair of banks, the first write driver 210 generates a first write driver signal (wdin1) and its complement (wdin1_n) responsive to a global data input signal gdin and its complement gdin_n. Similarly, the second write driver 235 generates a second write driver signal (wdin2) and its complement (wdin2_n) during a write operation to the second pair of banks.

As discussed analogously for memory 100, the first banks 220 and 230 are arranged such that the first bank 220 is closer to the first write driver 210 than the first bank 230. The first bank 220 is thus also designated as the first adjacent bank 220 whereas the first bank 230 is also designated as the first remote bank 230. Similarly, the second pair of banks are also arranged so that one of the banks in the second pair is closer to the second write driver 235.

The columns in the banks are multiplexed through corresponding write column multiplexers. The number of write column multiplexers for each bank depends upon the degree of the column multiplexing. In one implementation, each write column multiplexer selects from a group of two columns. Alternatively, a write column multiplexer may select from a group of four columns, or eight columns, and so on. For illustration clarity, just one write column multiplexer is shown in FIG. 2 for each bank. There is thus a write column multiplexer 225 (first remote MUX) for the first remote bank 230, a write column multiplexer 215 (first adjacent MUX) for the first adjacent bank 220, and a write column multiplexer 240 for the second adjacent bank (not illustrated). A second remote bank would also have a write column multiplexer (not illustrated). Each write column multiplexer selects from a group of n+1 columns, where n is a positive integer. Each column has a bit line (bl) and a complement bit line (blb) such that each write column multiplexer selects from a true and complement pair of bit lines from n+1 bit lines bl[n:0] and from n+1 complement bit lines blb[n:0].

In a write operation to the first adjacent bank 220, the write driver signals are subjected to relatively small amounts of resistance since the first write driver 210 is relatively close to the write column multiplexer 215 for the first adjacent bank 220. But in a write operation to the first remote bank 230, the write driver signals are propagated across the height of the first adjacent bank 220 to the write column multiplexer 225 for the first remote bank 230. In each write operation, one of the selected bit lines is grounded through a coupling to the vss_boost node and is then pulled to a negative bit line voltage during the boost period by the adaptive boost circuit 205. To provide a sufficient negative bit line boost despite the resistive losses to the write driver signals during a write operation to the first remote bank 230, the adaptive boost circuit 205 uses both the common boost capacitor and the remote boost capacitor to apply the negative boost. But in a write operation to the first adjacent bank 220, the adaptive boost circuit 205 uses only the common boost capacitor to apply the negative boost since the resistive losses to the write driver signals are reduced due to the relative closeness of the adjacent first bank 220 and its write column multiplexer 215 to the first write driver 210. The same bifurcation of the boost capacitors may occur during a write operation to the pair of second banks through the write driver 235 such that only the common boost capacitor is used in a write operation to the closer one of the banks in the pair of second banks whereas both the common boost capacitor and the remote boost capacitor are used during a write operation to the more remote one of the banks in the pair of second banks. It may thus be appreciated why the common boost capacitor is designated as “common” in that it is common to the write operations to the adjacent banks and to the more remote banks. In contrast, the remote boost capacitor is only used during a write operation to the remote banks.

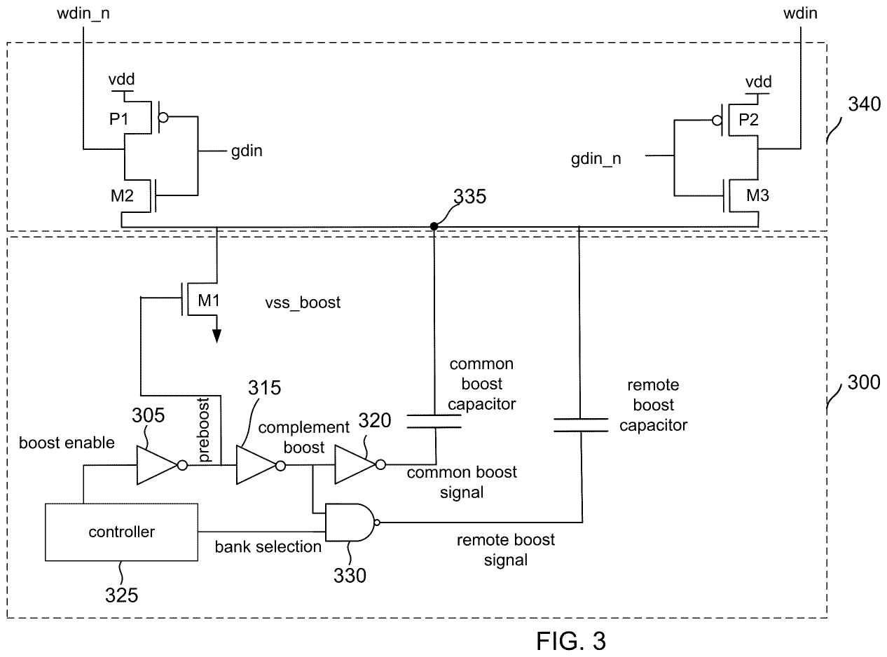

An example adaptive boost circuit 300 is shown in more detail in FIG. 3. A memory controller 325 asserts an active-high boost enable signal (boost enable) during the negative boost period. As used herein, a binary signal is deemed to be asserted when the signal is logically true, regardless of whether an active-high or active-low convention is used. In an active-high convention, a binary signal is thus asserted by being charged to a memory power supply voltage (vdd) and de-asserted by being grounded. Conversely, an active-low binary signal is asserted herein by being discharged to ground and de-asserted by being charged to the memory power supply voltage. During the non-boost portion of a write operation in which the negative boost is not applied, the memory controller 325 maintains a de-assertion of the boost enable signal. A first inverter 305 in a series of inverters includes an input terminal coupled to a first node for the boost enable signal to invert the boost enable signal. This inversion by the first inverter 305 produces a preboost signal (preboost) at an output terminal of the first inverter 305 that is coupled to a gate of an n-type metal-oxide semiconductor (NMOS) first transistor M1 having a source coupled to ground and a drain coupled to a vss_boost node 335. During the non-boost portion of a write operation, the first transistor M1 is thus switched on by the asserted preboost signal to ground the vss_boost node 335.

A write driver 340 includes a first serial pair of a p-type metal-oxide semiconductor (PMOS) transistor P1 and an NMOS transistor M2 and includes a second serial pair of a PMOS transistor P2 and an NMOS transistor M3. Transistors P1 and M2 form a first write driver inverter. Similarly, transistors P2 and M3 form a second write driver inverter. The sources of the transistors P1 and P2 couple to a node for the memory power supply voltage (vdd). Similarly, the sources of the transistors M2 and M3 (which function as ground input nodes to their respective write driver inverters) couple to the vss_boost node 335. The drains of the transistors P1 and M2 couple to a write driver lead for the write driver signal wdin_n. The global data input signal gdin drives the gates of the transistors P1 and M2 such that if the gdin signal is asserted, the transistor M2 switches on to ground the complement write driver signal wdin_n through the vss_boost node 335 (during the non-boost portion of a write operation). Conversely, if the gdin signal is de-asserted, the transistor P1 switches on to charge the complement write driver signal wdin_n to the memory power supply voltage.

The drains of the transistors P2 and M3 couple to a write driver lead for the write driver signal wdin. The complement global data input signal gdin_n drives the gates of the transistors P2 and M3 such that if the gdin_n signal is asserted, the transistor M3 switches on to ground the write driver signal wdin through the vss_boost node 335 (during the non-boost portion of a write operation). Conversely, if the gdin_n signal is de-asserted, the transistor P2 switches on to charge the write driver signal wdin to the memory power supply voltage.

Referring again to FIG. 2, the write driver signal wdin couples through the corresponding write column multiplexer to the bit line bl in the addressed one of the banks. Similarly, the complement write driver signal wdin_n couples through the corresponding write column multiplexer to the complement bit line blb in the addressed one of the banks. It may thus be seen that the write driver 340 grounds one of the bit lines during the non-boost portion of the write operation depending upon the binary value of the global data input signal gdin.

Referring again to the adaptive negative boost circuit 300, a second inverter 315 inverts the preboost signal to form a complement boost signal (complement boost). A third or final inverter 320 inverts the complement boost signal to form a common boost signal that drives a first terminal of the common boost capacitor. A second terminal of the common boost capacitor couples to the vss_boost node 335. The vss_boost node 335 is also denoted herein as a negative boost ground node. During the non-boost portion of the write operation, the first terminal of the common boost capacitor will thus be charged to the memory power supply voltage while its second terminal is grounded to charge the common boost capacitor.

The controller 325 asserts a bank selection signal (bank selection) while a write operation is directed to one of the remote banks and de-asserts the bank selection signal while a write operation is directed to one of the adjacent banks. To charge the remote boost capacitor, a logic gate such as a NAND gate 330 includes a first input terminal coupled to an input terminal of the third inverter 320 and includes a second input terminal coupled to a second node for the bank selection signal. The NAND gate 330 thus NANDs the complement boost signal with bank selection signal. Regardless of whether the bank selection signal is asserted, the grounded state of the complement boost signal during the non-boost portion of the write operation causes the NAND gate 330 to assert a remote boost signal that drives a first terminal of the remote boost capacitor. During the non-boost portion of the write operation, the first terminal of the remote boost capacitor will thus be charged to the memory power supply voltage while its second terminal coupled to the negative boost ground node 335 is grounded to charge the remote boost capacitor.

Although the boost enhancement disclosed herein is responsive to a bank selection signal, it will be appreciated that the bank selection signal is merely an example of a boost enhancement signal. For example, a boost enhancement signal may be generated based upon the word line address such that if the addressed word line is relatively displaced from the GIO, the memory controller 325 may assert a boost enhancement signal to cause an increase in the negative bit line boost through activation of an additional boost capacitor. Conversely, the memory controller 325 may de-assert the boost enhancement signal should the addressed word line be relatively closer to the GIO. The boost enhancement signal would thus replace the bank selection signal in such an implementation.

The memory controller 325 asserts the boost enable signal during the boost period. In that regard, the memory controller 325 times the boost period through, for example, a self-timed memory operation so that the boost period begins with the start of a final portion of a word line assertion period to the accessed bitcell. At the appropriate time during a write operation, the memory controller 325 charges the boost enable signal to the memory power supply voltage to assert the boost enable signal. Through the inversion in the first inverter 305, the preboost signal is thus switched off during the boost period so that the vss_boost node 335 floats with respect to ground. The complement boost signal is then asserted through the inversion by the second inverter 315 whereas the common boost signal is grounded through the inversion by the third inverter 320. The grounding of the common boost signal causes the charged common boost capacitor to apply a first negative bit line boost voltage to the vss_boost node 335. If the write operation is directed to an adjacent bank, the bank selection signal is grounded, which keeps the remote boost signal charged during the boost period. The remote boost capacitor thus remains charged during the boost period and does not contribute to the negative bit line voltage boosting if the write operation is directed to an adjacent bank. But if the write operation is directed to a remote bank, the memory controller asserts the bank selection signal. Since the complement boost signal is asserted during the boost period regardless of which bank is being written to, the assertion of both the bank selection signal and the complement boost signal causes the NAND gate 330 to de-assert the remote boost signal so that the remote boost capacitor in conjunction with the common boost capacitor applies a second negative bit line voltage to the vss_boost node 335.

The second negative bit line voltage is more negative than the first negative bit line voltage so that the negative boost is stronger during a write operation to a remote bank as compared to a write operation to an adjacent bank. In this fashion, power consumption is reduced yet an adequate amount of negative bit line boost is applied to the remote banks. The relative strength of the second negative bit line voltage compared to the first depends upon the capacitances of the boost capacitors. In one implementation, the common boost capacitor may have approximately a third (e.g., 35%) of the total boost capacitance from the boost capacitors. In such an implementation, the remote boost capacitor would have 65% of the total boost capacitance but it will be appreciated that the relative amounts of the capacitances may be varied in alternative implementations.

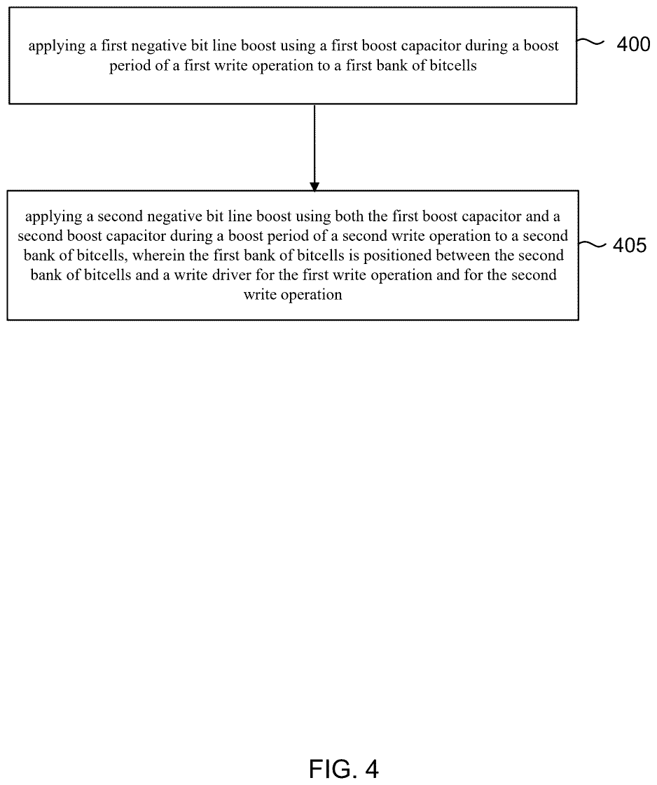

A flowchart for a write assist method of negative bit line boosting is shown in FIG. 4. The method includes an act 400 of applying a first negative bit line boost using a first boost capacitor during a boost period of a first write operation to a first bank of bitcells. The operation of the adaptive negative boost circuits 205 or 300 during the boost period of a write operation to one of the adjacent banks is an example of act 400. The method further includes an act 405 of applying a second negative bit line boost using both the first boost capacitor and a second boost capacitor during a boost period of a second write operation to a second bank of bitcells, wherein the first bank of bitcells is positioned between the second bank of bitcells and a write driver for the first write operation and for the second write operation. The operation of the adaptive negative boost circuits 205 or 300 during the boost period of a write operation to one of the remote banks is an example of act 400.

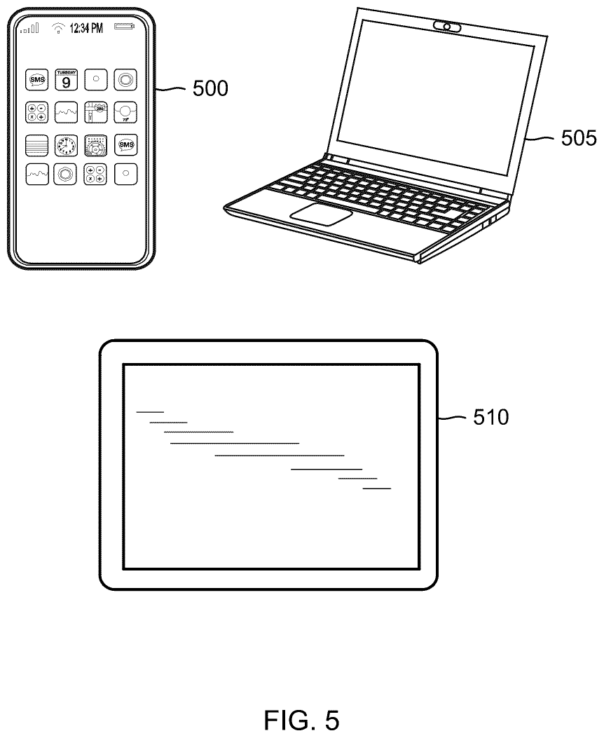

A memory with a negative bit line boost for write assist as disclosed herein may be incorporated into a wide variety of electronic systems. For example, as shown in FIG. 5, a cell phone 500, a laptop 505, and a tablet PC 510 may all include a memory configured for a negative bit line boosting as disclosed herein. Other exemplary electronic systems such as a music player, a video player, a communication device, and a personal computer may also be configured with memories constructed in accordance with the disclosure.

The disclosure will now be summarized in the following example clauses:
Clause 1. A memory, comprising:
   a write driver having a negative boost ground node;
   an adaptive negative boost circuit including:
   a first boost capacitor having a first terminal coupled to the negative boost ground node;
   a second boost capacitor having a first terminal coupled to the negative boost ground node;
   a series of inverters coupled between a first node for a boost enable signal and a second terminal of the first boost capacitor, wherein the series of inverters includes a final inverter having an output terminal coupled directly to the second terminal of the first boost capacitor; and
   a logic gate having a first input terminal coupled to a second node for a bank selection signal, a second input terminal coupled to an input terminal of the final inverter, and an output terminal coupled to a second terminal of the second boost capacitor.
Clause 2. The memory of clause 1, further comprising:
   a first bank of bitcells;
   a second bank of bitcells, wherein the first bank of bitcells is positioned between the second bank of bitcells and the write driver; and
   a controller configured to assert the bank selection signal during a write operation through the write driver to the second bank of bitcells.
Clause 3. The memory of any of clauses 1-2, wherein the series of inverters comprises a series of three inverters including:
   a first inverter having an input terminal coupled to the first node; and
   a second inverter having an input terminal coupled to an output terminal of the first inverter, wherein the final inverter is a third inverter in the series of three inverters and includes an input terminal coupled to an output terminal of the second inverter.
Clause 4. The memory of clause 3, further comprising:
   a first transistor coupled between ground and the negative boost ground node, wherein a gate of the first transistor is coupled to the output terminal of the first inverter.
Clause 5. The memory of clause 2, wherein the logic gate comprises a NAND gate.
Clause 6. The memory of clause 2, wherein the first bank of bitcells and the second bank of bitcells each comprises an array of static random-access memory (SRAM) bitcells.
Clause 7. The memory of any of clauses 1-6, wherein a capacitance of the first boost capacitor is less than a capacitance of the second boost capacitor.
Clause 8. The memory of any of clauses 1-7, wherein the memory is included within a cellular telephone.
Clause 9. The memory of any of the clauses 1-8, wherein the write driver includes a first write driver inverter having an input node coupled to a node for a global data input signal and having an output node coupled to a node for a first write driver signal, wherein a ground input node of the first write driver inverter is coupled to the negative boost ground node.
Clause 10. The memory of clause 9, wherein the write driver further includes a second write driver inverter having an input node coupled to a node for a complement of the global data input signal and having an output node coupled to a node for a second write driver signal, wherein a ground input node of the second write driver inverter is coupled to the negative boost ground node.
Clause 11. A write assist method for a memory, comprising:
   applying a first negative bit line boost using a first boost capacitor during a boost period of a first write operation to a first bank of bitcells; and
   applying a second negative bit line boost using both the first boost capacitor and a second boost capacitor during a boost period of a second write operation to a second bank of bitcells, wherein the first bank of bitcells is positioned between the second bank of bitcells and a write driver for the first write operation and for the second write operation.
Clause 12. The write assist method of clause 11, further comprising:
   charging a first terminal of the first boost capacitor and a first terminal of the second boost capacitor to a memory power supply voltage while grounding a second terminal of the first boost capacitor and a second terminal of the second boost capacitor during a non-boost portion of the first write operation and of the second write operation.
Clause 13. The write assist method of clause 12, wherein applying the first negative bit line boost using the first boost capacitor during the boost period of the first write operation comprises:
   floating the second terminal of the first boost capacitor and of the second boost capacitor while grounding the first terminal of the first boost capacitor and while maintaining the charging of the first terminal of the second boost capacitor.
Clause 14. The write assist method of clause 13, wherein applying the second negative bit line boost using both the first boost capacitor and the second boost capacitor comprises:
   floating the second terminal of the first boost capacitor and of the second boost capacitor while grounding the first terminal of the first boost capacitor and while grounding the first terminal of the second boost capacitor.
Clause 15. A memory, comprising:
   a write driver having a negative boost ground node; and
   an adaptive negative boost circuit configured to use a first boost capacitance to apply a first negative boost voltage to the negative boost ground node during a boost period of a write operation to a first bank of bitcells by the write driver and configured to use the first boost capacitance and a second boost capacitance to apply a second negative boost voltage to the negative boost ground node during a boost period of a write operation to second bank of bitcells by the write driver.
Clause 16. The memory of clause 15, further comprising:
   a memory controller configured to assert a boost enable signal during each boost period, wherein the adaptive negative boost circuit includes:
   a first boost capacitor having the first boost capacitance; and
   a series of inverters coupled between a node for the boost enable signal and a first terminal of the first boost capacitor, and wherein a second terminal of the first boost capacitor is coupled to the negative boost ground node.
Clause 17. The memory of clause 16, wherein the memory controller is further configured to assert a bank enhancement signal during the write operation to the second bank and to de-assert the bank selection signal during the write operation to the first bank and the series of inverters includes a final inverter having an output terminal coupled to the first terminal of the first boost capacitor, and wherein the adaptive negative boost circuit further includes:
   a second boost capacitor having the second boost capacitance; and
   a logic gate having a first input terminal coupled to an input terminal of the final inverter, a second input terminal coupled to a node for the bank enhancement signal, and an output terminal coupled to a first terminal of the second boost capacitor, wherein a second terminal of the second boost capacitor is coupled to the negative boost ground node.
Clause 18. The memory of clause 17, wherein the logic gate comprises a NAND gate.
Clause 19. The memory of any of clauses 17-18, wherein the series of inverters comprises a series of three inverters.
Clause 20. The memory of clause 19, further comprising:
   a transistor coupled between the negative boost ground node and ground, wherein a first inverter in the series of three inverters includes an output terminal coupled to a gate of the transistor.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

We claim:

1. A memory, comprising:
a write driver having a negative boost ground node;
an adaptive negative boost circuit including:
a first boost capacitor having a first terminal coupled to the negative boost ground node;
a second boost capacitor having a first terminal coupled to the negative boost ground node;
a series of inverters coupled between a first node for a boost enable signal and a second terminal of the first boost capacitor, wherein the series of inverters includes a final inverter having an output terminal coupled directly to the second terminal of the first boost capacitor; and
a logic gate having a first input terminal coupled to a second node for a bank selection signal, a second input terminal coupled to an input terminal of the final inverter, and an output terminal coupled to a second terminal of the second boost capacitor.

2. The memory of claim 1, further comprising:
a first bank of bitcells;
a second bank of bitcells, wherein the first bank of bitcells is positioned between the second bank of bitcells and the write driver; and
a controller configured to assert the bank selection signal during a write operation through the write driver to the second bank of bitcells.

3. The memory of claim 1, wherein the series of inverters comprises a series of three inverters including:
a first inverter having an input terminal coupled to the first node; and
a second inverter having an input terminal coupled to an output terminal of the first inverter, wherein the final inverter is a third inverter in the series of three inverters and includes an input terminal coupled to an output terminal of the second inverter.

4. The memory of claim 3, further comprising:
a first transistor coupled between ground and the negative boost ground node, wherein a gate of the first transistor is coupled to the output terminal of the first inverter.

5. The memory of claim 2, wherein the logic gate comprises a NAND gate.

6. The memory of claim 2, wherein the first bank of bitcells and the second bank of bitcells each comprises an array of static random-access memory (SRAM) bitcells.

7. The memory of claim 1, wherein a capacitance of the first boost capacitor is less than a capacitance of the second boost capacitor.

8. The memory of claim 1, wherein the memory is included within a cellular telephone.

9. The memory of claim 1, wherein the write driver includes a first write driver inverter having an input node coupled to a node for a global data input signal and having an output node coupled to a node for a first write driver signal, wherein a ground input node of the first write driver inverter is coupled to the negative boost ground node.

10. The memory of claim 9, wherein the write driver further includes a second write driver inverter having an input node coupled to a node for a complement of the global data input signal and having an output node coupled to a node for a second write driver signal, wherein a ground input node of the second write driver inverter is coupled to the negative boost ground node.

11. A write assist method for a memory, comprising:
applying a first negative bit line boost using a first boost capacitor during a boost period of a first write operation to a first bank of bitcells; and
applying a second negative bit line boost using both the first boost capacitor and a second boost capacitor during a boost period of a second write operation to a second bank of bitcells, wherein the first bank of bitcells is positioned between the second bank of bitcells and a write driver for the first write operation and for the second write operation.

12. The write assist method of claim 11, further comprising:
charging a first terminal of the first boost capacitor and a first terminal of the second boost capacitor to a memory power supply voltage while grounding a second terminal of the first boost capacitor and a second terminal of the second boost capacitor during a non-boost portion of the first write operation and of the second write operation.

13. The write assist method of claim 12, wherein applying the first negative bit line boost using the first boost capacitor during the boost period of the first write operation comprises:
floating the second terminal of the first boost capacitor and of the second boost capacitor while grounding the first terminal of the first boost capacitor and while maintaining the charging of the first terminal of the second boost capacitor.

14. The write assist method of claim 13, wherein applying the second negative bit line boost using both the first boost capacitor and the second boost capacitor comprises:
floating the second terminal of the first boost capacitor and of the second boost capacitor while grounding the first terminal of the first boost capacitor and while grounding the first terminal of the second boost capacitor.

15. A memory, comprising:
a write driver having a negative boost ground node; and
an adaptive negative boost circuit configured to use a first boost capacitance to apply a first negative boost voltage to the negative boost ground node during a boost period of a write operation to a first bank of bitcells by the write driver and configured to use the first boost capacitance and a second boost capacitance to apply a second negative boost voltage to the negative boost ground node during a boost period of a write operation to second bank of bitcells by the write driver.

16. The memory of claim 15, further comprising:
a memory controller configured to assert a boost enable signal during each boost period, wherein the adaptive negative boost circuit includes:
a first boost capacitor having the first boost capacitance; and
a series of inverters coupled between a node for the boost enable signal and a first terminal of the first boost capacitor, and wherein a second terminal of the first boost capacitor is coupled to the negative boost ground node.

17. The memory of claim 16, wherein the memory controller is further configured to assert a boost enhancement signal during the write operation to the second bank and to de-assert the boost enhancement signal during the write operation to the first bank and the series of inverters includes a final inverter having an output terminal coupled to the first terminal of the first boost capacitor, and wherein the adaptive negative boost circuit further includes:
a second boost capacitor having the second boost capacitance; and
a logic gate having a first input terminal coupled to an input terminal of the final inverter, a second input terminal coupled to a node for the boost enhancement signal, and an output terminal coupled to a first terminal of the second boost capacitor, wherein a second terminal of the second boost capacitor is coupled to the negative boost ground node.

18. The memory of claim 17, wherein the logic gate comprises a NAND gate.

19. The memory of claim 17, wherein the series of inverters comprises a series of three inverters.

20. The memory of claim 19, further comprising:
a transistor coupled between the negative boost ground node and ground, wherein a first inverter in the series of three inverters includes an output terminal coupled to a gate of the transistor.
